(19) United States
(12) Patent Application Publication
(10) Pub. No.: US 2012/0146644 A1
(43) Pub. Date: Jun. 14, 2012

(54) INTEGRATED FIELD GENERATION UNIT FOR AN MRT SYSTEM

(76) Inventors: Peter Dietz, Furth (DE); Johann Schuster, Oberasbach (DE); Stefan Stocker, Großenseebach (DE); Axel Vom Endt, Erlangen (DE)

(21) Appl. No.: 13/160,317

(22) Filed: Jun. 14, 2011

(30) Foreign Application Priority Data
Jun. 15, 2010 (DE) DE102010023846.5

(51) Int. Cl. G01R 33/44

(52) U.S. Cl. 324/318

(57) ABSTRACT

The present embodiments relate to a magnetic resonance tomography system having a basic-field field generation device for generating a basic magnetic field. The magnetic resonance tomography system also includes a gradient-field field generation device for generating a gradient field, where the basic-field field generation device and the gradient-field field generation device are arranged in an evacuatable low-pressure housing.

This application claims the benefit of DE 10 2010 023 846.5, filed Jun. 15, 2010.

### BACKGROUND

The present embodiments relate to an MRT system.

Magnetic resonance tomography devices for examining objects or patients using magnetic resonance tomography are known from DE10314215B4, for example.

Field generation subunits in magnetic resonance tomography devices may be implemented in a modular design. A superconducting magnet, for example, that generates a static magnetic field B0 may be located externally. A gradient coil system that generates time-variable magnetic fields for spatial encoding may be located inside a cylindrical bore of the magnet. An RF transmit coil that generates a B1 field for exciting nuclear spins in an examination subject is contained within the gradient coil system. This type of design allows simple assembly and installation.

### SUMMARY

The present embodiments may obviate one or more of the drawbacks or limitations in the related art. For example, an imaging system may be optimized. An integrated field generation system may be provided.

### BRIEF DESCRIPTION OF THE DRAWINGS

FIG. 1 is a schematic view of one embodiment of an MRT system; and

FIG. 2 is a schematic view of an MRT system.

### DETAILED DESCRIPTION OF THE DRAWINGS

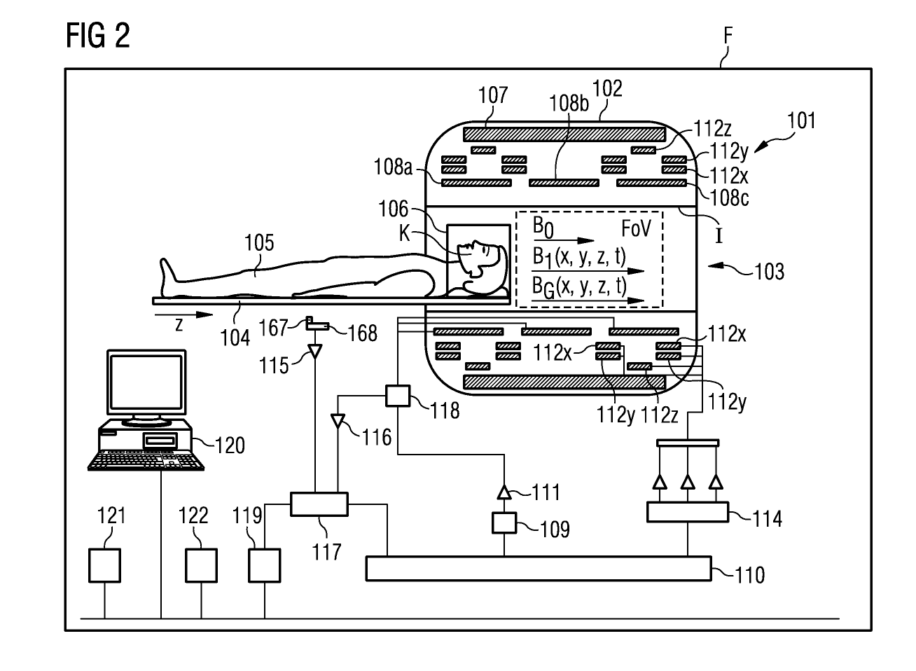

FIG. 2 shows an imaging magnetic resonance device MRT 101 (e.g., located in a shielded room or Faraday cage F) having a whole-body magnetic coil 102 with a tubular space 103 (e.g., a tunnel shaped bore), for example, into which a patient couch 104 bearing a body 105 (e.g., an examination subject such as a patient) with or without local coil arrangement 106 may be moved in the direction of the arrow z in order to generate images of the patient 105 using an imaging method. In the embodiment shown in FIG. 2, the local coil arrangement 106 is placed on the patient 105. Images may be generated in a local region (e.g., a field of view) using the local coil arrangement 106. Signals of the local coil arrangement 106 may be evaluated (e.g., converted into images, stored or displayed) by an evaluation device (e.g., elements 115, 117, 119, 120, 121) of the magnetic resonance device MRT 101. The evaluation device may be connected, for example, via coaxial cable or wirelessly to the local coil arrangement 106.

In order to utilize magnetic resonance imaging to examine the body 105 (e.g., the examination subject or the patient) using the magnetic resonance device MRT 101, different magnetic fields that are precisely coordinated with one another in terms of temporal and spatial characteristics are radiated onto the body 105. A strong magnet (e.g., a cryomagnet 107) in a measurement chamber having the tunnel-shaped bore 103, for example, generates a strong static main magnetic field B₀ ranging, for example, from 0.2 Tesla to 3 Tesla or more. The body 105 that is to be examined, supported on the patient couch 104, is moved into a region of the main magnetic field B₀ that is approximately homogeneous in the area of observation field of view (FoV). Nuclear spins of atomic nuclei of the body 105 are excited via magnetic radio-frequency excitation pulses B1(x, y, z, t) that are emitted via a radio-frequency antenna (and/or a local coil arrangement). The radio-frequency antenna is shown in FIG. 2 in simplified form as a body coil 108 (e.g., a multipart body coil 108a, 108b, 108c). Radio-frequency excitation pulses are generated, for example, by a pulse generation unit 109 that is controlled by a pulse sequence control unit 110. Following amplification using a radio-frequency amplifier 111, the radio-frequency excitation pulses are routed to the radio-frequency antenna 108. The radio-frequency system shown in FIG. 2 is indicated only schematically. In other embodiments, more than one pulse generation unit 109, more than one radio-frequency amplifier 111 and a plurality of radio-frequency antennas 108 a, b, c are used in the magnetic resonance device MRT 101.

The magnetic resonance device MRT 101 also has gradient coils 112x, 112y, 112z, using which magnetic gradient fields are radiated in the course of a measurement in order to provoke selective layer excitation and for spatial encoding of the measurement signal. The gradient coils 112x, 112y, 112z are controlled by a gradient coil control unit 114 that, like the pulse generation unit 109, is connected to the pulse sequence control unit 110.

Signals transmitted by the excited nuclear spins (e.g., the atomic nuclei in the examination subject) are received by the body coil 108 and/or at least one local coil arrangement 106, amplified using associated radio-frequency preamplifiers 116, and processed further and digitized by a receiving unit 117. The recorded measured data is digitized and stored in the form of complex numeric values in a k-space matrix. An associated MR image may be reconstructed using a multidimensional Fourier transform from the k-space matrix populated with values.

In the case of a coil that may be operated in both transmit and receive mode (e.g., the body coil 108 or a local coil), correct signal forwarding is controlled by an upstream-connected duplexer 118.

An image processing unit 119 generates an image from the measured data, the image being displayed to a user via an operator console 120 and/or stored in a memory unit 121. A central computer unit 122 controls the individual system components.

In MR tomography, images having a high signal-to-noise ratio (SNR) may be acquired using local coil arrangements (e.g., loops, local coils). The local coil arrangements are antenna systems that are attached in the immediate vicinity on (anterior), under (posterior) or in the body. In the course of an MR measurement, the excited nuclei induce a voltage in the individual antennas of the local coil. The induced voltage is amplified by a low-noise preamplifier (e.g., LNA, preamp) and forwarded to receive electronics. High-field systems (e.g., 1.5 T and more) are also used in the case of high-resolution images in order to improve the signal-to-noise ratio. If more individual antennas may be connected to an MR receiving system than there are receivers present, a switching array (e.g., RCCS) is installed between receive antennas and receivers. The switching array routes the currently active receive channels (e.g., receive channels lying in the field of view of the magnet) to the receivers. This enables more coil elements to be connected than there are receivers, since in the case of whole-body coverage, coils that are located in the FoV or in the homogeneity volume of the magnet are read out.

Local coil arrangement 106 may be used to designate an antenna system that may consist of, for example, one antenna element or a plurality of antenna elements (e.g., coil elements) configured as an array coil. The individual antenna elements are implemented, for example, as loop antennas (e.g., loops) or butterfly or saddle coils. The local coil arrangement 106 includes, for example, coil elements, a preamplifier, further electronics (e.g., standing wave traps), a housing, and supports. The local coil arrangement 106 may also include a cable with a plug, using which the local coil arrangement 106 is connected to the MRT system. A receiver 168 mounted on the system side filters and digitizes a signal received, for example, wirelessly by a local coil 106 and passes the data to a digital signal processing device. The digital signal processing device may derive an image or a spectrum from the data acquired using a measurement and makes the image available to the user, for example, for subsequent diagnosis by the user and/or for storage in a memory.

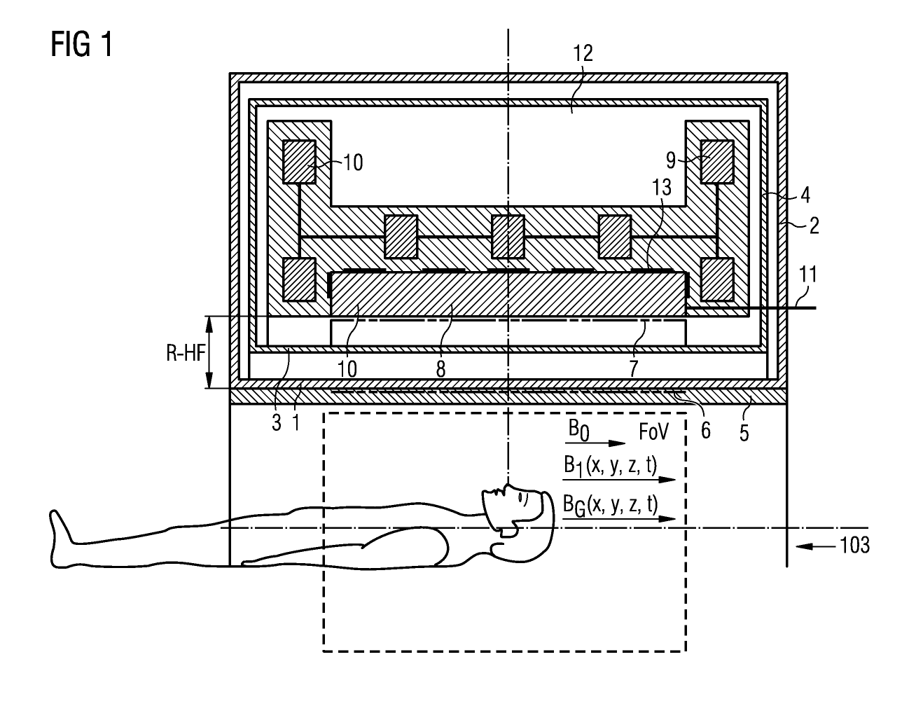

FIG. 1 shows one embodiment of a magnetic resonance tomography (MRT) system.

The MRT system 101 shown in FIG. 1 includes a basic-field field generation device with, for example, superconducting helium-cooled magnetic coils 9 (e.g., having heatsinks on the coils) for generating a basic field B₀. The MRT system 101 also includes a gradient-field field generation device with gradient coils 8 (having subsystems for gradient fields in directions x, y, z) for generating a gradient field B_{G}(x, y, z, t), and an RF-field generation device with RF coils 6 (e.g., one or more RF coils 6; RF transmit coils) for generating an RF field B₁(x, y, z, t).

The gradient coils 8 and the superconducting helium-cooled magnetic coils 9 (e.g., field generation subunits) are spatially integrated in FIG. 1.

The basic-field field generation device and the gradient-field field generation device are arranged in a low-pressure housing 2 (e.g., a vacuum housing) that may be evacuated to create a vacuum 12 (e.g., at least a pressure lower than ambient pressure or a virtual vacuum) and may be configured, for example, as metallic.

The gradient-field field generation device with the gradient coils 8 may be accommodated in the vacuum 12 of a magnet system (e.g., B0 field magnet system. The vacuum 12 (e.g., “vacuum” may be a pressure lower than ambient pressure or a suitable, approximate vacuum) between the gradient coils 8 and the vacuum housing 2 may also serve simultaneously as an RF reflow space R-HF of the RF coils 6 (e.g., for fields of the RF transmit coils 6).

In this arrangement, an RF-tight shield 7 (e.g. largely shielding against RF radiation) may be carried on the inside of the gradient coils 8.

Transmit antennas of the RF transmit coils 6 may be mounted on the inside 1 of the vacuum housing 2 during the MRT installation and are protected on the inside 1 by a contact protection device 5 (e.g., an inner lining; implemented as soft plastic and/or soft foam with a smooth surface) on the inside 1 (e.g., facing toward the FoV or the examination subject). In addition, the inner lining 5 may also be provided as acoustic insulation.

The gradient coils 8 in the vacuum 12 serve as a carrier (e.g., a weight-bearing carrier) of the magnetic coils 9 (e.g., B0 field magnetic coils) together, with which the gradient coils 8 and the magnetic coils may be cast to form a combined unit 10, thus enabling previously used separate carriers (e.g., for the magnetic coils 9) to be dispensed with.

The gradient coils 8 may also be a separate component independent of the carrier of the magnetic coils 9.

In one embodiment, one or more shielding segments 13 (e.g., a copper layer) may be provided in order to shield the superconducting magnetic coils 9 from a stray field of the gradient coils 8.

In one embodiment, separate field generation units are integrated.

In one embodiment, the vacuum housing (e.g., the vacuum housing 2 of the vacuum 12 in the MRT system 101) and/or a cold shield 3, 4 (e.g., a radiation and cold shield) are implemented as electrically non-conducting, at least on inner sides (e.g., facing in the direction of the FoV; on the inside 1 of the vacuum housing 2 and/or on a side of the radiation and cold shield 3, 4).

In another embodiment, the gradient coils 8 are arranged in the vacuum 12, and vacuum-tight (e.g., impermeable also in the case of a vacuum for water; sufficiently thick and/or insulated) power supply and cooling water connections 11 for the gradient coils 8 are provided.

In one embodiment, the superconductor of the MRT system 101 may be relatively small. In another embodiment, a design without a separate carrier for the magnetic coils 9 and without a separate tube for the RF transmit coils 6 may be realized.

In one embodiment, the main field magnet may be short.

A suitable arrangement of the gradient coils 8 in the vacuum 12 may produce an acoustically insulating effect.

An inner lining (e.g., on the FoV side) made of foam may effect a reduction in noise (e.g., insofar as noise is generated by vibrations of the internal tube). A soft surface provides greater comfort in the event of contact (e.g., by the elbows). If magnetic coils with smaller radii are used, the MRT system may have small external dimensions and a low weight.

While the present invention has been described above by reference to various embodiments, it should be understood that many changes and modifications can be made to the described embodiments. It is therefore intended that the foregoing description be regarded as illustrative rather than limiting, and that it be understood that all equivalents and/or combinations of embodiments are intended to be included in this description.

1. A magnetic resonance tomography system comprising:
a basic-field field generation device operable to generate a basic magnetic field; and
a gradient-field field generation device operable to generate a gradient field,
wherein the basic-field field generation device and the gradient-field field generation device are each arranged in an evacuatable low-pressure housing.

2. The magnetic resonance tomography system as claimed in claim 1, wherein the basic-field field generation device and the gradient-field field generation device are arranged in the same evacuatable low-pressure housing.

3. The magnetic resonance tomography system as claimed in claim 2, wherein the basic-field field generation device and the gradient-field field generation device comprise coils that are arranged in the same evacuatable low-pressure housing.

4. The magnetic resonance tomography system as claimed in claim 1, wherein the gradient-field field generation device comprises an RF shield for shielding against RF radiation, the RF shield being on a side of the gradient-field field generation device facing toward a field of view of the magnetic resonance tomography system.

5. The magnetic resonance tomography system as claimed in claim 1, further comprising an RF field generation device,
wherein the RF field generation device comprises a transmit antenna, the transmit antenna being arranged outside of the evacutable low-pressure housing.

6. The magnetic resonance tomography system as claimed in claim 5, wherein the transmit antenna of the RF field generation device is positioned on the inside of the evacutable low-pressure housing, is attached to the evacutable low-pressure housing, or is positioned on the inside of the evacutable low-pressure housing and attached to the evacutable low-pressure housing.

7. The magnetic resonance tomography system as claimed in claim 5, wherein the transmit antenna of the RF field generation device comprises a contact protection unit.

8. The magnetic resonance tomography system as claimed in claim 5, wherein the transmit antenna of the RF field generation device is enclosed only by a contact protection layer on an inside of the transmit antenna facing toward a field of view.

9. The magnetic resonance tomography system as claimed in claim 1, wherein the gradient-field field generation device is a carrier of magnetic coils of the basic-field field generation device at least inside the evacutable low-pressure housing.

10. The magnetic resonance tomography system as claimed in claim 1, wherein the evacutable low-pressure housing is a carrier of the gradient-field field generation device.

11. The magnetic resonance tomography system as claimed in claim 9, wherein coils of the gradient-field field generation device and the magnetic coils of the basic-field field generation device are a single unit.

12. The magnetic resonance tomography system as claimed in claim 1, further comprising one or more field shielding elements provided between the basic-field field generation device and coils of the gradient-field generation device.

13. The magnetic resonance tomography system as claimed in claim 1, wherein the evacuatable low-pressure housing, a cold shield, or the evacuatable low-pressure housing and the cold shield are implemented as electrically non-conducting on all sides or at least on a side facing toward a field of view.

14. The magnetic resonance tomography system as claimed in claim 1, wherein coils of the gradient-field field generation device have power supply connections, water connections, or power supply and water connections that are leak-tight with respect to a vacuum.

15. The magnetic resonance tomography system as claimed in claim 4, further comprising an RF field generation device,
wherein the RF field generation device comprises a transmit antenna, the transmit antenna being arranged outside of the low-pressure housing.

16. The magnetic resonance tomography system as claimed in claim 7, wherein the contact protection unit is a layer made of foam, plastic, or foam and plastic.

17. The magnetic resonance tomography system as claimed in claim 6, wherein the transmit antenna of the RF field generation device is enclosed only by a contact protection layer on an inside of the transmit antenna facing toward a field of view.

18. The magnetic resonance tomography system as claimed in claim 9, wherein the evacutable low-pressure housing is a carrier of the gradient-field field generation device.

19. The magnetic resonance tomography system as claimed in claim 12, wherein the one or more field shielding elements shield an area of the magnetic coils of the basic-field field generation device from a field emitted by the coils of the gradient-field field generation device.

20. The magnetic resonance tomography system as claimed in claim 11, wherein the coils of the gradient-field field generation device have power supply connections, water connections, or power supply and water connections that are leak-tight with respect to a vacuum.
